(19) United States
(12) Patent Application Publication
(10) Pub. No.: US 2023/0204685 A1
(43) Pub. Date: Jun. 29, 2023

(54) DETECTOR AND IMAGE FORMING APPARATUS

(71) Applicants: Eiji Tsuchida, Tokyo (JP); Dai Sakamoto, Kanagawa (JP)

(72) Inventors: Eiji Tsuchida, Tokyo (JP); Dai Sakamoto, Kanagawa (JP)

(73) Assignee: Ricoh Company, Ltd., Tokyo (JP)

(21) Appl. No.: 18/065,107

(22) Filed: Dec. 13, 2022

(30) Foreign Application Priority Data
Dec. 23, 2021 (JP) 2021-209658

(51) Int. Cl. G01R 31/68; G01R 1/20; H04N 1/00

(52) U.S. Cl. CPC G01R 31/68; G01R 1/203; H04N 1/00965; H04N 1/00888; H04N 1/00037; H04N 1/00063; H04N 1/00074

(57) ABSTRACT

A detector includes a board with a connector, a measurement resistor, a switch, and circuitry. The board with the connector is coupled to an external board. The measurement resistor is connected to the connector. The switch is connected to the measurement resistor and switches on and off an electric current flowing thorough the measurement resistor. The circuitry measures a potential difference between both ends of the measurement resistor, and determines, based on the potential difference measured, a coupling state of the external board with respect to the connector. The circuitry controls the switch to switch on and off the electric current flowing through the measurement resistor.

### CROSS-REFERENCE TO RELATED APPLICATION

This patent application is based on and claims priority pursuant to 35 U.S.C. § 119(a) to Japanese Patent Application No. 2021-209658, filed on Dec. 23, 2021, in the Japan Patent Office, the entire disclosure of which is hereby incorporated by reference herein.

### BACKGROUND

### Technical Field

The present disclosure relates to a detector and an image forming apparatus.

### Related Art

A detector has been known that detects the coupling states (ON state, OFF state, and malfunction state) of an external board coupled to a board. However, such a detector may adopt an expensive switch for detecting erroneous coupling. For this reason, there is a demand for a detector that includes an inexpensive system that functions as the expensive switch for detecting erroneous coupling, and detects the coupling state of an external board and reduces power consumption.

### SUMMARY

According to an embodiment of the present disclosure, a detector includes a board with a connector, a measurement resistor, a switch, and circuitry. The board with the connector is coupled to an external board. The measurement resistor is connected to the connector. The switch is connected to the measurement resistor and switches on and off an electric current flowing thorough the measurement resistor. The circuitry measures a potential difference between both ends of the measurement resistor, and determines, based on the potential difference measured, a coupling state of the external board with respect to the connector. The circuitry controls the switch to switch on and off the electric current flowing through the measurement resistor.

According to another embodiment of the present disclosure, an image forming apparatus includes the detector.

### BRIEF DESCRIPTION OF THE DRAWINGS

A more complete appreciation of the disclosure and many of the attendant advantages and features thereof can be readily obtained and understood from the following detailed description with reference to the accompanying drawings, wherein:

FIG. 1 is a diagram illustrating a configuration of a detector according to an embodiment;

FIG. 2 is a diagram illustrating a configuration example of a monitoring circuit included in the detector according to the embodiment;

FIG. 3 is a diagram illustrating an example of a functional configuration of an integrated circuit (IC) included in the detector according to the embodiment;

FIG. 4 is a flowchart illustrating an example of a procedure of processing by the IC included in the detector according to the embodiment;

FIG. 5 is a diagram illustrating a modification of the monitoring circuit included in the detector according to the embodiment; and

FIG. 6 is a flowchart illustrating a modification of a procedure of processing by the IC included in the detector according to the embodiment.

The accompanying drawings are intended to depict embodiments of the present disclosure and should not be interpreted to limit the scope thereof. The accompanying drawings are not to be considered as drawn to scale unless explicitly noted.

### DETAILED DESCRIPTION

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Hereinafter, embodiments are described with reference to the accompanying drawings. In order to facilitate understanding of the description, the same components in the drawings are denoted by the same reference numerals as much as possible, and redundant description is omitted.

Hereinafter, embodiments of the present disclosure are described with reference to the attached drawings.

Configuration of Detector

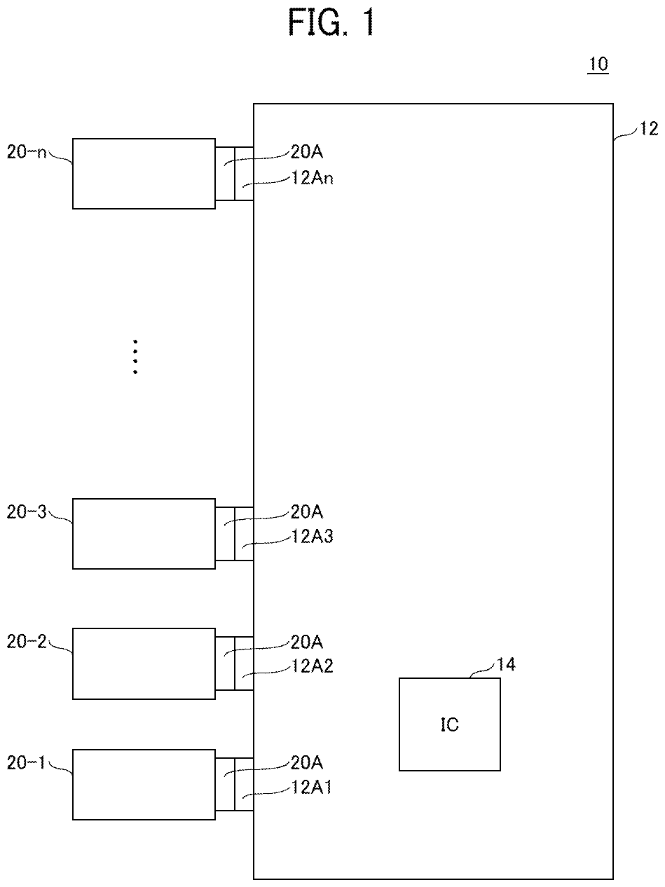

FIG. 1 is a diagram illustrating a configuration of a detector 10 according to an embodiment of the present disclosure. As illustrated in FIG. 1, the detector 10 includes a control board 12, an integrated circuit (IC) 14, and memory boards 20-1 to 20-n.

The control board 12 is an example of a “board”, such as a printed circuit board (PCB), and is a flat sheet-like member having a rectangular shape in plan view, in the present embodiment. The control board 12 is provided with connectors 12A1 to 12An at one side portion of the rectangular shape. The connectors 12A1 to 12An are an example of a “connector”. For example, the connectors 12A1 to 12An are female connectors.

Each of the memory boards 20-1 to 20-n is an example of an “external board”, and has a rectangular shape in plan view. Each of the memory boards 20-1 to 20-n is provided with a connector 20A at one side portion of the rectangular shape facing the control board 12. The connector 20A is an example of an “external connector”. For example, the connector 20A is a male connector. At the connector 20A, each of the memory boards 20-1 to 20-n is coupled to the corresponding connector 12A among the connectors 12A1 to 12An included in the control board 12. Each of the memory boards 20-1 to 20-n is coupled to the control board 12 to function as, for example, an extension memory of the control board 12.

The IC 14 is mounted on the control board 12. The IC 14 performs various control of the detector 10. For example, the IC 14 determines the coupling state of each of the memory boards 20-1 to 20-n coupled to the control board 12. The IC 14 includes, for example, a microcomputer, a control application specific integrated circuit (ASIC), or the like.

Configuration of Monitoring Circuit

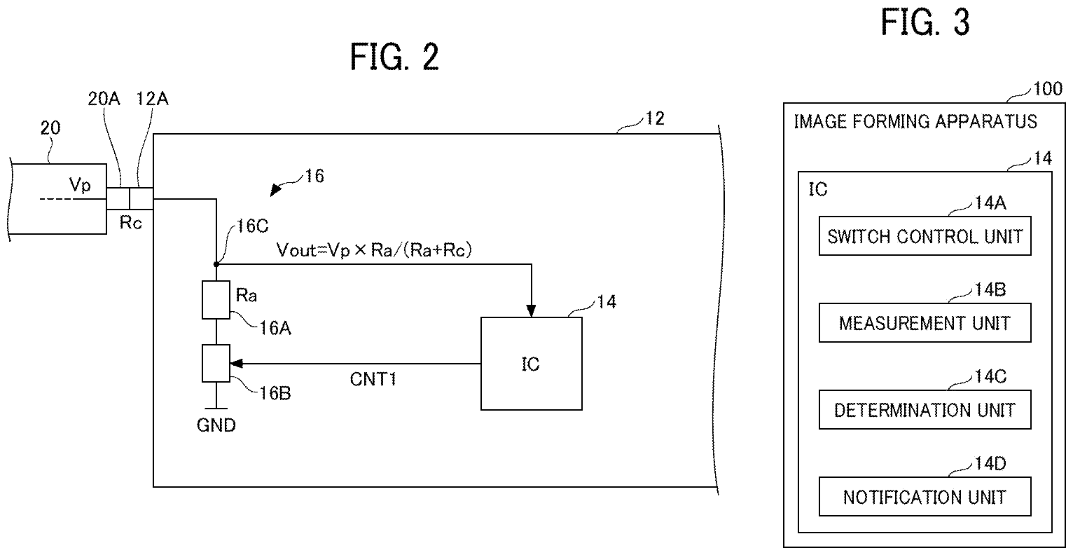

FIG. 2 is a diagram illustrating a configuration example of a monitoring circuit 16 included in the detector 10. As illustrated in FIG. 2, in the detector 10 according to the embodiment, the monitoring circuit 16 is provided on the control board 12. The monitoring circuit 16 illustrated in FIG. 2 is configured to determine the coupling state of one of the memory boards 20.

In the control board 12, the monitoring circuit 16 is provided between the connector 12A and a ground (GND). The monitoring circuit 16 includes a pull-down resistor 16A and a switch 16B connected to each other in series. The pull-down resistor 16A is an example of a “measurement resistor”. The pull-down resistor 16A has a resistance component Ra. The monitoring circuit 16 also includes a measurement point 16C between the connector 12A and the pull-down resistor 16A.

In the monitoring circuit 16, a direct current voltage Vp is applied to the pull-down resistor 16A from the memory board 20 via the connector 20A and the connector 12A. In the monitoring circuit 16, the IC 14 is connected to the measurement point 16C between the connector 12A and the pull-down resistor 16A. As a result, the IC 14 measures a potential difference Vout between both ends of the pull-down resistor 16A. The IC 14 determines the coupling state of the memory board 20 on the basis of the measured potential difference Vout between both ends of the pull-down resistor 16A.

For example, when the coupling state between the connector 20A and the connector 12A is “normal”, the resistance value of the connector resistance component Rc is substantially 0 [Ω] (0 [Ω] or a value approximate to 0 [Ω]).

For example, when the coupling state between the connector 20A and the connector 12A is “incomplete” (half-insertion or a poor contact state), the resistance value of the connector resistance component Rc is R [Ω].

For example, when the connector 20A and the connector 12A are “not coupled”, the resistance value of the connector resistance component Rc is ∞ [Ω].

The potential difference Vout between both ends of the pull-down resistor 16A is obtained by the following Expression (1), that is, varies according to the resistance value of the connector resistance component Rc.

Vout=Vp×Ra/(Ra+Rc) (1)

Therefore, the IC 14 measures the potential difference Vout between both ends of the pull-down resistor 16A to determine, on the basis of the potential difference Vout, whether the coupling state of the memory board 20 is any one of “normal”, “incomplete”, and “not coupled”.

In a case where a current constantly flows through the monitoring circuit 16, there is a possibility that the amount of power and the amount of heat generation increase. To this end, in the detector 10 according to the embodiment, the switch 16B is provided between the pull-down resistor 16A and a ground (GND) in the monitoring circuit 16. As a result, the detector 10 according to the embodiment switches the switch 16B between an ON state and an OFF state to switch between a state of the monitoring circuit 16 in which a current is flowing and a state of the monitoring circuit 16 in which no current is flowing. In the detector 10 according to the embodiment, the switch 16B is switched to the ON state under the control of a control signal CNT1 from the IC 14, so that the IC 14 can measure the potential difference Vout between both ends of the pull-down resistor 16A to determine the coupling state of the memory board 20.

For example, a transistor or a field effect transistor (FET) is used for the switch 16B. In a case where a transistor is used for the switch 16B, the switch configuration is simple and inexpensive. On the other hand, in a case where an FET is used for the switch 16B, the switch configuration is simple, and the power consumption of the switch 16B is suppressed.

Functional Configuration of IC

FIG. 3 is a diagram illustrating an example of a functional configuration of the IC 14 included in the detector 10, which is included in an image forming apparatus 100.

As illustrated in FIG. 3, the IC 14 includes a switch control unit 14A, a measurement unit 14B, a determination unit 14C, and a notification unit 14D.

The switch control unit 14A outputs a control signal CNT1 to the switch 16B to control the switching between the ON state and the OFF state of the switch 16B.

The IC 14 of the present embodiment, as implemented on a Printed Circuit Board (PCB), configured to electrically connected in the image forming apparatus 100. The image forming apparatus 100 of the present embodiment would be, such as a copying machine, a printer, a scanner apparatus, a facsimile apparatus, and the like. Specifically, the present invention can be applied to a multifunction machine having a copy function, a printer function, a scanner function, a facsimile function, and the like.

For example, when the image forming apparatus 100, which is the apparatus at a level higher than the level of the detector 10, is switched to a “normal mode”, the switch control unit 14A outputs a control signal CNT1 to the switch 16B to switch the switch 16B to the ON state.

For example, when the image forming apparatus, which is an apparatus at a level higher than the level of the detector 10, is switched to an “energy saving mode”, the switch control unit 14A outputs a control signal CNT1 to the switch 16B to switch the switch 16B to the OFF state.

The measurement unit 14B measures the potential difference Vout between both ends of the pull-down resistor 16A when the switch 16B is in the ON state under the control of the switch control unit 14A.

The determination unit 14C determines the coupling state of the memory board 20 on the basis of the potential difference Vout measured by the measurement unit 14B. For example, the determination unit 14C determines whether the coupling state of the memory board 20 is any one of “normal”, “incomplete”, and “not coupled” on the basis of the potential difference Vout measured by the measurement unit 14B.

In a case where a determination result by the determination unit 14C is not “normal”, the notification unit 14D notifies the user of a warning by a predetermined notification method (for example, displaying of a warning, a warning sound, or the like).

Each function of the IC 14 can be implemented by one or a plurality of processing circuits. The “processing circuit” herein includes a processor programmed so that software can execute each function, such as a processor implemented by an electronic circuit. The “processing circuit” herein also includes devices, such as an application specific integrated circuit (ASIC), a digital signal processor (DSP), a field programmable gate array (FPGA), and conventional circuit modules, designed to perform the recited functions.

Procedure of Processing by IC

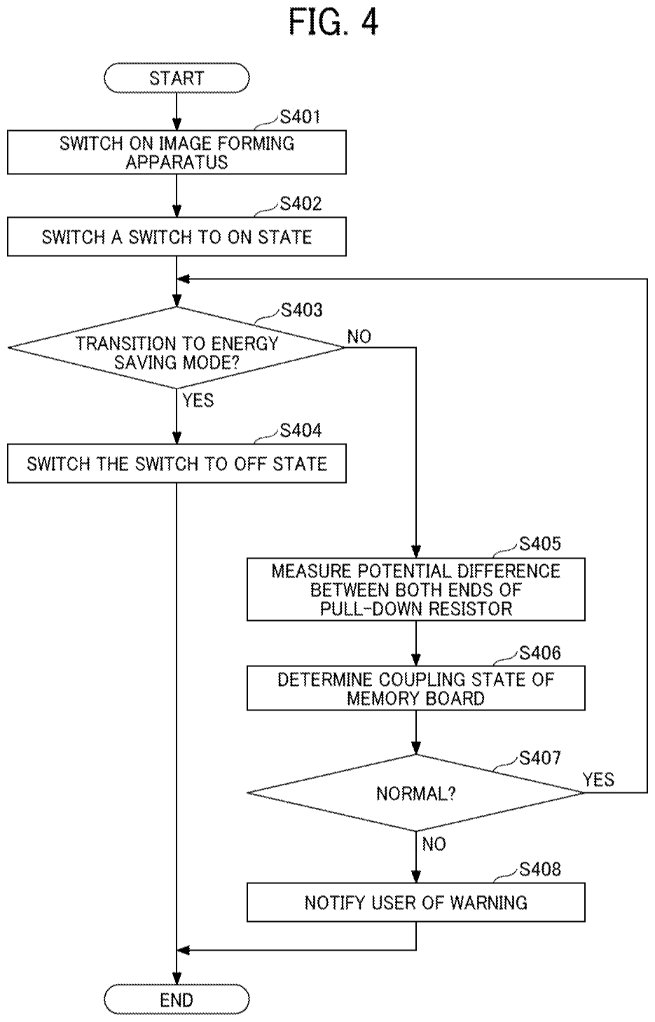

FIG. 4 is a flowchart illustrating an example of a procedure of processing by the IC 14 included in the detector 10.

First, when the power supply of the image forming apparatus, which is an apparatus at a level higher than the level of the detector 10, is switched to the ON state (step S401), the switch control unit 14A outputs a control signal CNT1 to the switch 16B to switch the switch 16B to the ON state (step S402).

Next, the IC 14 ascertains whether or not the image forming apparatus has been switched to the “energy saving mode” (step S403).

In a case where in step S403, it is ascertained that the image forming apparatus has been switched to the “energy saving mode” (Yes in step S403), the switch control unit 14A outputs a control signal CNT1 to the switch 16B to switch the switch 16B to the OFF state (step S404). Then the IC 14 ends the series of processing illustrated in FIG. 4.

On the other hand, in a case where in step S403, it is ascertained that the image forming apparatus has not been switched to the “energy saving mode” (No in step S403), the measurement unit 14B measures the potential difference Vout between both ends of the pull-down resistor 16A (step S405).

Then the determination unit 14C determines the coupling state of the memory board 20 on the basis of the potential difference Vout measured in step S405 (step S406).

The IC 14 also ascertains whether or not a determination result in step S406 is “normal” (step S407).

In a case where in step S407, it is ascertained that a determination result in step S406 is “normal” (Yes in step S407), the IC 14 returns the processing to step S403.

On the other hand, in a case where in step S407, it is ascertained that a determination result in step S406 is not “normal” (No in step S407), the notification unit 14D notifies the user of a warning by a predetermined notification method (for example, displaying of a warning, a warning sound, or the like) (step S408). Then the IC 14 ends the series of processing illustrated in FIG. 4.

Modification of Monitoring Circuit

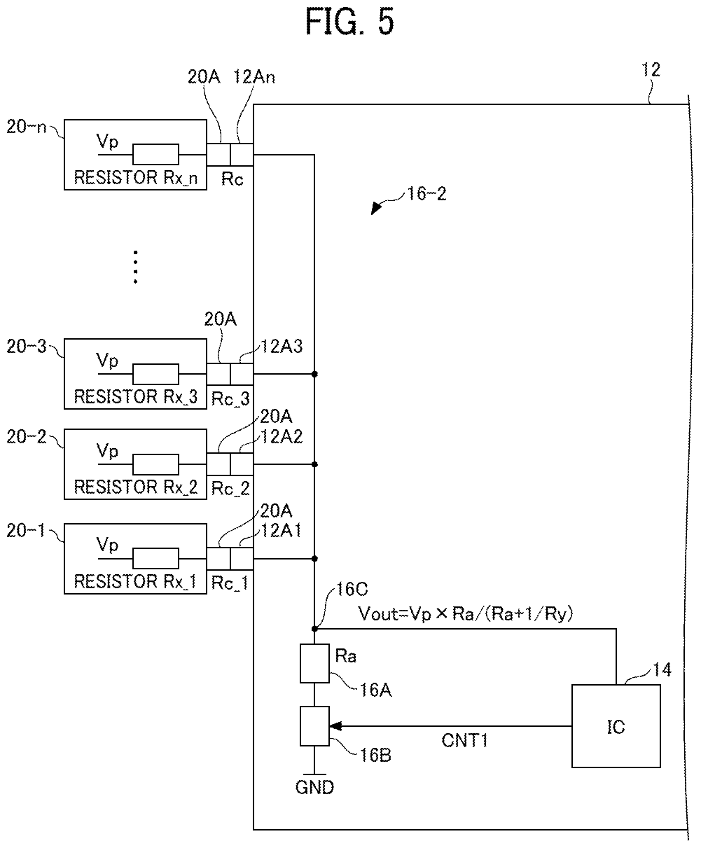

FIG. 5 is a diagram illustrating a modification of the monitoring circuit 16 included in the detector 10. As illustrated in FIG. 5, in the detector 10 according to the embodiment, a monitoring circuit 16-2, which is a modification of the monitoring circuit 16, is provided on the control board 12. The monitoring circuit 16-2 illustrated in FIG. 5 is configured to determine the coupling state of each of the plurality of memory boards 20 (20-1 to 20-n).

In the monitoring circuit 16-2, a pull-down resistor 16A is connected to each of the plurality of connectors 12A (12A1 to 12An). In the monitoring circuit 16-2, a direct current voltage Vp is applied to the pull-down resistor 16A from each of the plurality of memory boards 20 via the connector 20A and the connector 12A. In the monitoring circuit 16-2, a measurement point 16C is provided between each of the plurality of connectors 12A and the pull-down resistor 16A. As a result, the IC 14 measures a potential difference Vout between both ends of the pull-down resistor 16A. The IC 14 determines the coupling state of each of the plurality of memory boards 20 on the basis of the measured potential difference Vout between both ends of the pull-down resistor 16A.

In the monitoring circuit 16-2, the potential difference Vout between both ends of the pull-down resistor 16A is obtained by the following Expression (2), that is, varies according to resistors Rx (Rx_1 to Rx_n) of the plurality of memory boards 20 (20-1 to 20-n) and a plurality of connector resistance components Rc (RC_1 to Rc_n).

Vout=Vp×Ra/(Ra+1/Ry) (2)

1/Ry is obtained by the following Expression (3).

$$\begin{matrix}[ Math . 1 ] & \\ 1 / Ry = {\sum }_{k = 1}^{n} ( 1 / ( Rx\_k + Rc\_k ) ) & ( 3 )\end{matrix}$$

For example, when the coupling states of all the memory boards 20 are “normal”, the parallel combined resistance value of the preset resistors Rx of the plurality of memory boards 20 is 1/Ry [Ω]. Therefore, the potential difference Vout corresponds to 1/Ry [Ω].

On the other hand, when the coupling state of any one of the memory boards 20 is “incomplete” or “not coupled”, the parallel combined resistance value of the resistors Rx of the plurality of memory boards 20 varies from 1/Ry [Ω]. Therefore, the potential difference Vout varies from the potential difference Vout corresponding to 1/Ry [Ω].

In the present embodiment, the plurality of memory boards 20 includes the resistors Rx having resistance values different from each other among the plurality of memory boards 20. Therefore, in the present embodiment, when the coupling state of any one of the memory boards 20 is “incomplete” or “not coupled”, the parallel combined resistance value of the resistors Rx of the plurality of memory boards 20 and the potential difference Vout between both ends of the pull-down resistor 16A vary by a variation amount corresponding to the resistance value of the resistor Rx of the memory board 20 in question.

Therefore, the IC 14 measures the potential difference Vout between both ends of the pull-down resistor 16A to determine, on the basis of a variation amount of the potential difference Vout, whether the coupling state of any one of the memory boards 20 is “incomplete” or “not coupled”.

For example, in a case where the number of coupled memory boards 20 is three, the parallel combined resistance value is obtained as the following formula.

1/Ry=1/(Rx_1+Rc_1)+1/(Rx_2+Rc_2)+1/(Rx_3+Rc_3)=((Rx_2+Rc_2)(Rx_3+Rc_3)+(Rx_1+Rc_1)(Rx_3+Rc_3)+(Rx_1+Rc_1)(Rx_2+Rc_2))/(Rx_1+Rc_1)(Rx_2+Rc_2)(Rx_3+Rc_3)

Ry=(Rx_1+Rc_1)(Rx_2+Rc_2)(Rx_3+Rc_3)/((Rx_2+Rc_2)(Rx_3+Rc_3)+(Rx_1+Rc_1)(Rx_3+Rc_3)+(Rx_1+Rc_1)(Rx_2+Rc_2))

Therefore, if different resistance values are set in advance for Rx_1, Rx_2, and Rx_3, the resistance value varies in a case of a coupling failure, and thus the potential difference between both ends of the pull-down resistor 16A also varies. Thus, the detected potential difference Vout is compared with preset parameters to identify the memory board 20 in which the coupling failure is occurring.

Also in the monitoring circuit 16-2 illustrated in FIG. 5, a switch 16B is provided between the pull-down resistor 16A and a ground (GND). As a result, the detector 10 according to the embodiment switches the switch 16B between an ON state and an OFF state to switch between a state of the monitoring circuit 16-2 in which a current is flowing and a state of the monitoring circuit 16-2 in which no current is flowing. In the detector 10 according to the embodiment, the switch 16B is switched to the ON state under the control of a control signal CNT1 from the IC 14, so that the IC 14 can measure the potential difference Vout between both ends of the pull-down resistor 16A to determine the coupling state of each of the plurality of the memory boards 20.

Modification of Procedure of Processing by IC

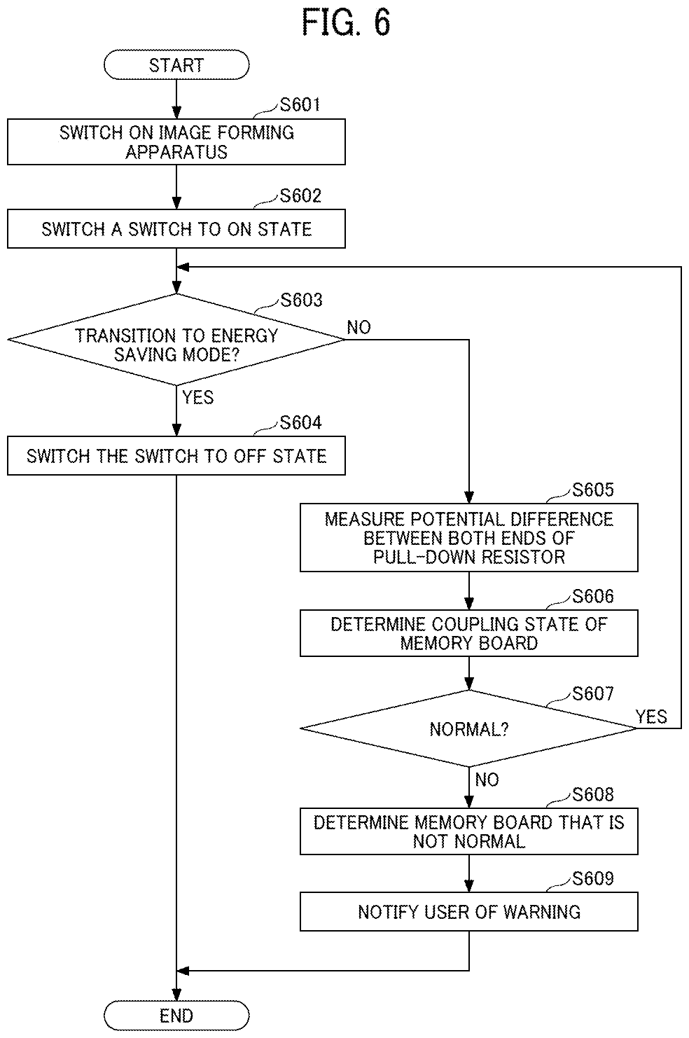

FIG. 6 is a flowchart illustrating a modification of the procedure of processing by the IC 14 included in the detector 10. A series of processing illustrated in FIG. 6 corresponds to the monitoring circuit 16-2 illustrated in FIG. 5.

First, when the power supply of the image forming apparatus, which is an apparatus at a level higher than the level of the detector 10, is switched to the ON state (step S601), the switch control unit 14A outputs a control signal CNT1 to the switch 16B to switch the switch 16B to the ON state (step S602).

Next, the IC 14 ascertains whether or not the image forming apparatus has been switched to the “energy saving mode” (step S603).

In a case where in step S603, it is ascertained that the image forming apparatus has been switched to the “energy saving mode” (Yes in step S603), the switch control unit 14A outputs a control signal CNT1 to the switch 16B to switch the switch 16B to the OFF state (step S604). Then the IC 14 ends the series of processing illustrated in FIG. 6.

On the other hand, in a case where in step S603, it is ascertained that the image forming apparatus has not been switched to the “energy saving mode” (No in step S603), the measurement unit 14B measures the potential difference Vout between both ends of the pull-down resistor 16A (step S605).

Then the determination unit 14C determines the coupling states of the memory boards 20 on the basis of the potential difference Vout measured in step S605 (step S606). The determination unit 14C determines one of “normal”, “incomplete”, and “not coupled” as the coupling states of the memory boards 20.

The IC 14 also ascertains whether or not a determination result in step S606 is “normal” (step S607).

In a case where in step S607, it is ascertained that a determination result in step S606 is “normal” (Yes in step S607), the IC 14 returns the processing to step S603.

On the other hand, in a case where in step S607, it is ascertained that a determination result in step S606 is not “normal” (No in step S607), the determination unit 14C determines, on the basis of the potential difference Vout measured in step S605, the memory board 20 whose coupling state is not “normal” among the plurality of memory boards 20 (step S608).

The notification unit 14D notifies the user of a warning by a predetermined notification method (for example, displaying of a warning, a warning sound, or the like) (step S609). At this time, the notification unit 14D may notify the user of the memory board 20 whose coupling state is not “normal” determined in step S608.

Then the IC 14 ends the series of processing illustrated in FIG. 6.

As described above, the detector 10 according to an embodiment of the present disclosure includes the connector 12A that is provided for the control board 12 and to which the memory board 20 is coupled, the pull-down resistor 16A connected to the connector 12A, the measurement unit 14B that measures a potential difference Vout between both ends of the pull-down resistor 16A, the determination unit 14C that determines, on the basis of the potential difference Vout measured by the measurement unit 14B, the coupling state of the memory board 20 with respect to the connector 12A, the switch 16B that is connected to the pull-down resistor 16A and can switch off a current flowing through the pull-down resistor 16A, and the switch control unit 14A that controls the switch 16B.

As a result, the detector 10 determines the coupling state of the memory board 20 with respect to the connector 12A with a relatively simple configuration, and controls the switch 16B to switch off a current flowing through the pull-down resistor 16A when the measurement of the potential difference Vout is unnecessary. Therefore, the detector 10 according to the embodiment detects the coupling state of the memory board 20 coupled to the control board 12, and reduces the power consumption.

The detector 10 includes the plurality of connectors 12A to which the plurality of memory boards 20 is coupled, and the pull-down resistor 16A connected to each of the plurality of connectors 12A, and the determination unit 14C determines, on the basis of the potential difference Vout measured by the measurement unit 14B, the coupling states of the plurality of memory boards 20 with respect to the plurality of connectors 12A.

As a result, the detector 10 determines the coupling states of the plurality of memory boards 20 with respect to the plurality of connectors 12A with a relatively simple configuration, and controls the switch 16B to switch off a current flowing through the pull-down resistor 16A when the measurement of the potential difference Vout is unnecessary. Therefore, the detector 10 according to the embodiment detects the coupling states of the plurality of memory boards 20 coupled to the control board 12, and reduces the power consumption.

In the detector 10, the plurality of memory boards 20 has resistance values different from each other among the plurality of memory boards 20, and the determination unit 14C determines, on the basis of the potential difference Vout measured by the measurement unit 14B, each of the coupling states of the plurality of memory boards 20 with respect to the connectors 12A.

As a result, the detector 10 determines each of the coupling states of the plurality of memory boards 20 with respect to the plurality of connectors 12A with a relatively simple configuration.

The detector 10 includes the notification unit 14D that notifies the user of a warning in response to a determination result that is not normal by the determination unit 14C.

As a result, the detector 10 notifies the user of a warning to prompt the user to normally couple the memory board 20.

In the detector 10, the switch 16B includes a transistor or an FET.

As a result, in the detector 10, the switch 16B has a simple switch configuration, and the power consumption of the switch 16B is suppressed.

The above-described embodiments are illustrative and do not limit the present disclosure. Thus, numerous additional modifications and variations are possible in light of the above teachings. For example, elements and/or features of different illustrative embodiments may be combined with each other and/or substituted for each other within the scope of the present disclosure.

Any one of the above-described operations may be performed in various other ways, for example, in an order different from the one described above.

Each of the functions of the described embodiments may be implemented by one or more processing circuits or circuitry. Processing circuitry includes a programmed processor, as a processor includes circuitry. A processing circuit also includes devices such as an application specific integrated circuit (ASIC), digital signal processor (DSP), field programmable gate array (FPGA), and conventional circuit components arranged to perform the recited functions.

1. A detector comprising:
a board with a connector to couple an external board;
a measurement resistor connected to the connector;
a switch connected to the measurement resistor and configured to switch on and off an electric current flowing through the measurement resistor; and
circuitry configured to:
measure a potential difference between both ends of the measurement resistor;
determine, based on the potential difference measured, a coupling state of the external board with respect to the connector; and
control the switch to switch on and off the electric current flowing through the measurement resistor.

2. The detector according to claim 1, further comprising a plurality of connectors, including the connector, to couple a plurality of external boards including the board,
wherein the measurement resistor is connected to each of the plurality of connectors, and
wherein the circuitry is configured to determine, based on the potential difference measured, coupling states of the plurality of external boards with respect to the plurality of connectors.

3. The detector according to claim 2,
wherein the plurality of external boards have resistance values different from each other, and
wherein the circuitry is configured to determine, based on the potential difference measured, each one of the coupling states of the plurality of external boards with respect to the plurality of connectors.

4. The detector according to claim 1,
wherein the circuitry is configured to notify a user of a warning in response to a determination result that the coupling state is abnormal.

5. The detector according to claim 1,
wherein the switch includes a transistor.

6. The detector according to claim 1,
wherein the switch includes a field effect transistor.

7. An image forming apparatus comprising the detector according to claim 1.
